(19) United States
(12) Patent Application Publication
(10) Pub. No.: US 2005/0123856 A1
(43) Pub. Date: Jun. 9, 2005

(54) Process for the manufacture of flexographic printing plates

(76) Inventor: David H. Roberts, Carlsbed, CA (US)

Correspondence Address: John L. Cordani;Carmody & Torrance LLP, 50 Leavenworth Street, P.O. Box 1110, Waterbury, CT, 06721-1110, US

(21) Appl. No.: 10/729,533

(22) Filed: Dec. 5, 2003

(51) Int. Cl. G03F 7/00

(52) U.S. Cl. 430/300; 430/306; 430/348

(57) ABSTRACT

A process is disclosed for the solvent-less development and production of flexographic printing plates. Relatively thin metal backed printing plate elements with a layer of photopolymer are selectively exposed to actinic radiation heated to at least 70° C. and then blotted to form a relief image. The process is particularly suited to the production of flexographic printing plates for printing newspapers and other publications.

### FIELD OF THE INVENTION

This invention pertains to a method for preparing flexographic printing plates and, in particular, a method for thermally treating a photosensitive element to form a relief structure suitable for flexographic printing. The method disclosed is particularly efficient in producing said plates with minimum production time. The flexographic plates produced are especially suited to use in printing newspapers and other publications.

### BACKGROUND

The first flexographic printing plates were produced from natural or synthetic rubber compositions which were cured in a mold to create the shape and relief images required. More recently, photopolymer compositions have been used to create flexographic printing plates. Generally, these photopolymer based printing plates comprise a substrate, photopolymer layer(s) and a removable coversheet. The photopolymer plate is then formed by stripping off the coversheet, imagewise exposing the photopolymer layer to actinic radiation through a negative and developing away the unexposed areas of the photopolymer layer by washing in a solvent. After development, generally, the plates must be dried for an extended period of time.

Many different types of cross-linkable resins (binders) and monomers are known in the art to be useful in producing printing plates. Their properties can be adjusted as taught in the art to provide rigidity, flexibility or other desired properties. Some photopolymer materials useful in producing printing plates, and in the practice of this invention, include materials disclosed in U.S. Pat. Nos. 4,578,504; 4,638,040; and 4,786,657, the teachings each of which are incorporated by reference herein in their entirety.

In addition to the extended time periods required to produce photopolymer printing plates using the foregoing process technology, noxious waste by-products are produced in the solvent development procedures. As a result, processes have been sought which will eliminate, or at least minimize, the production of waste by-products and streamline the plate production process.

As a result, this invention proposes a process whereby photopolymer printing plates are prepared using heat and the differential melting temperature between cured and uncured photopolymer to develop the latent image. The basic parameters of this process are known as described in U.S. Pat. Nos. 5,175,072 and 3,264,103 and in PCT WO 01/88615, the teachings each of which are incorporated herein in their entirety. However, the inventors here have discovered unexpected improvements to this process which allow much more rapid processing of flexographic plates, thereby making the process useable by newspapers and other publications which require quick turnaround times and high productivity.

### SUMMARY OF THE INVENTION

This invention comprises a process for the manufacture of flexographic printing plates, said process comprising:
a). selectively exposing a printing plate element to actinic radiation wherein the printing plate element comprises:
   1. a metallic substrate; and
   2. at least one photopolymer layer upon said metallic substrate wherein the thickness of said photopolymer layer is not more than 22 mils and the durometer of the photopolymer layer, when cured, is at least 55 Shore A,
      such that selected portions of the photopolymer layer are cured;
b). heating the printing plate element to at least 70° C., thereby selectively softening or melting portions of the photopolymer layer; and
c). contacting the heated printing plate element with a material which will absorb or otherwise remove the softened or melted portion of the printing plate element.

### DETAILED DESCRIPTION OF THE INVENTION

The process proposed herein is an improved process for the manufacture of photopolymer printing plates wherein solvent development of the imaged printing plate element is replaced with heat development thereof. Thus the process allows for the elimination of development solvents and the lengthy plate drying times needed to remove the solvent. The speed and efficiency of the process allow for use of the process in the manufacture of flexographic plates for printing newspapers and other publications where quick turnaround times and high productivity are important.

The invention therefore comprises a process for the manufacture of flexographic printing plates, said process comprising:
a). selectively exposing a printing plate element to actinic radiation wherein the printing plate element comprises:
   1. a metallic substrate; and
   2. a photopolymer layer upon said metallic substrate wherein the thickness of said photopolymer is not more that about 22 mils and the durometer of the photopolymer layer, when cured, is at least 55 Shore A;
   such that selected portions of the photopolymer layer are cured
b. heating the printing plate element to at least 70° C., thereby selectively softening or melting portions of the photopolymer layer; and
c. contacting the heated printing plate element with a material which will absorb or otherwise remove the softened or melted portions of the photopolymer thereby yielding an image.

The printing plate element useful in the process of this invention comprises at least two layers, a metallic substrate and a photopolymer layer. The metallic substrate may be comprised of various metals or alloys including steel, stainless steel, aluminum, nickel, copper, and alloys comprising any of the foregoing. The thickness of the metallic substrate depends upon the particular application, but is generally between 3 and 14 mils, preferably between 5 and 11 mils. The metallic substrate provides a base structure for the photopolymer layer, allows for heated development at higher temperatures and allows for effective mounting on the printing press.

The photopolymer layer allows for the creation of the desired image and provides a printing surface. The photopolymers used generally comprise one or more of the following materials; binders; monomers, photoinitiators and other performance additives. Photopolymer compositions useful in the practice of this invention include those described in U.S. patent application Ser. No. 10/353,446 filed Jan. 29, 2003, the teachings of which are incorporated herein by reference in their entirety, with or without the inclusion of nano particles in such photopolymer compositions. The teachings of WO/0188615 A1 are also incorporated herein by reference in their entirety. Various photopolymers such as those based on polystyrene-isoprene-styrene, polystyrene-butadiene-styrene, polyurethanes and/or thiolenes as binders are useful. Preferable binders are polystyrene-isoprene-styrene, and polystyrene-butadiene-styrene, especially block co-polymers of the foregoing. It is also preferred that the photopolymer comprise not more than about 82% by weight binder. The printing plate element must have at least one, but may have more than one, photopolymer layer. The thickness of photopolymer on the substrate should not be more than about 22 mils. Photopolymer thicker than about 22 mils will substantially reduce the speed and efficiency of the process and may cause a deterioration in print quality, especially when printing publications. The cured photopolymer should preferably have a hardness durometer of at least 55 Shore A as measured by ASTM standard no. D2240. The cured photopolymer should also have a melt flow index of at least 0.5 gr/10 minutes at 140° C. as measured by ASTM method D1238-99.

The composition of the photopolymer should be such that there exists a substantial difference in the melt temperature between the cured and uncured polymer. It is precisely this difference that allows the creation of an image in the photopolymer when heated. The uncured photopolymer (i.e. the portions of the photopolymer not contacted with actinic radiation) will melt or substantially soften while the cured photopolymer will remain solid and in tact at the temperature chosen. Thus the difference in melt temperature allows the uncured photopolymer to be selectively removed thereby creating an image.

The first step in the process involves selectively exposing the printing plate element to actinic radiation. Selective exposure is generally accomplished in one of three related ways. In the first alternative, a photographic negative with transparent areas and substantially opaque areas is used to selectively block the transmission of actinic radiation to the printing plate element. In the second alternative, the photopolymer layer is coated with an actinic radiation (substantially) opaque layer, which is also sensitive to laser ablation. A laser is then used to ablate selected areas of the actinic radiation opaque layer creating an in situ negative. The printing plate element is then flood exposed through the in situ negative. In the third alternative, a focused beam of actinic radiation is used to selectively expose the photopolymer. Any of these alternative methods is acceptable, with the criteria being the ability to selectively expose the photopolymer to actinic radiation thereby selectively curing portions of the photopolymer.

Once the photopolymer layer of the printing plate element has been selectively exposed to actinic radiation, it is then ready to develop using heat. As such, the printing plate element is heated to at least 70° C. The exact temperature will depend upon the properties of the particular photopolymer being used. However, two primary factors should be considered in determining the development temperature:
1. The development temperature is preferably set between the melt temperature of the uncured photopolymer on the low end and the melt temperature of the cured photopolymer on the upper end. This will allow selective removal of the photopolymer thereby creating the image.
2. The higher the development temperature, the quicker the process time will be. However, the development temperature should not be so high as to exceed the melt temperature of the cured photopolymer or so high that it will degrade the cured photopolymer. The temperature should be sufficient to melt or substantially soften the uncured photopolymer thereby allowing it to be removed. The proposed construction of the printing plate element with a metal substrate allows for higher development temperatures and quicker process times.

The heated printing element is then contacted with a material that will absorb or otherwise remove the softened or melted uncured photopolymer. This can be done using screen mesh or with an absorbant fabric. Either woven or non-woven fabric may be used and the fabric can be polymer based or paper. However, the fabric must be able to withstand the operating temperatures involved. In either case it is best accomplished using rollers to bring the material and the heated printing plate element into contact. This removal process is generally referred to as “blotting”. In most cases, the heating and blotting process must be repeated several times in order to obtain effective removal of the uncured photopolymer. Upon completion of the blotting process, the printing plate element is preferably post-exposed to further artinic radiation, cooled and then ready for use. It has been surprisingly discovered that using the construction of this invention, photopolymers can be effectively processed at much higher temperatures than previously thought without damage to the photopolymer and without decreasing the quality of the printing plate.

This process is particularly suited to the production of printing plates for use in printing newspapers and other publications where quick turnaround is necessary. In fact, it is believed that standard sized printing plates can be processed commercially in less that 2 minutes using standard commercial equipment. The plates produced are of high quality and the overall cost of production of the printing plates is more favorable than that of the older organic solvent or aqueous development process.

As noted previously, the basic elements of the printing plate element are a metal substrate and at least one photopolymer layer. However, depending upon the particular application, the printing plate element may also comprise other optional components. For instance, it is frequently preferable to use a removable coversheet over the photopolymer layer to protect the layer during handling. If used, the coversheet is removed either just before or just after the selective exposure to actinic radiation. Other layers such as slip layer or masking layers as described in U.S. Pat. No. 5,925,500, the teachings of which are incorporated herein by reference in their entirety, can also be used.

This invention is further described in, but is not limited by, the following examples:

### EXAMPLE I

These examples illustrate the significant benefits to plate processing speed and dimensional stability afforded by the use of metallic substrates and thin relief.

Steel Substrate Preparation: In the order given, 45.00 parts of NeoRez® R-966 polyurethane dispersion (Zeneca Resins), 2.50 parts of Alcogum® SL-76 acrylic emulsion (National Starch & Chemical), 1.6 parts of sodium hydroxide, 50.4 parts of deionized water and 0.50 parts of Surfynol® 440 surfactant (Air Products & Chemical Inc) were mixed at room temperature for 15 minutes to form a primer composition.

A length of 0.0066-inch thick tin-free steel was pretreated by sequentially washing with 0.1 N aqueous sodium hydroxide and deionized water, then dried with hot air. The primer composition was applied via roll-coating to the cleaned steel to a wet thickness of 25-40 microns. The sheet was dried in a forced-air oven at 400° F. for 75 seconds.

Resin mixing and plate making: A mixture of 5.6 parts of 1,6-hexanediol diacrylate (SR-238 from Sartomer), 5.6 parts of trimethylolpropane trimethacrylate (SR-350 from Sartomer), 2.8 parts of benzil dimethyl ketal (Irgacure® 651 from Ciba Specialty Chemicals), 1.2 parts of butylated hydroxy toluene (BHT from Sherex Chemical Company), 0.17 part of calcium stearate (Spectrum Chemical Corporation), 0.04 part of Irganox® 1010 (Ciba Specialty Chemicals) and 0.006 parts of Sandoplast® Red Violet R dye (Clariant Corp) was stirred until all the solid components were dissolved.

79.8 parts styrene-isoprene-styrene block copolymer (Kraton® D-1107 from Kraton Polymers) were mixed with 4.8 parts of Shellflex® 371 plasticizer (Shell Chemicals) in a HAAKE Rheodrive 3000 mixer at 105° C. until well blended. Incremental amounts of the above solution were added to the polymer. The resin was mixed until homogenous. The complete photopolymer resin had a melt flow index 2.9 grams/10 min at 140° C. using ASTM method D1238-99. A cured sample of the resin had a Shore A hardness of 62 by ASTM method D-2240.

The photosensitive resin described above was heat-pressed at 80° C. onto a sheet of pre-coated steel substrate to produce a 17-mil thick resin layer. A cover sheet bearing a Macromelt 6900 slip layer was laminated onto the top surface of the plate. Those skilled in the art will be familiar with coversheets and slip layers useful for flexographic printing plates.

Plate Imaging and Thermal Processing: The cover sheet was stripped away from the plate (leaving the slip layer on the resin surface) and the recording layer was exposed for 10 minutes on a Supratech Systems FB3 exposure unit (equipped with 10R lamps) through an image-bearing mask.

The exposed flexo plate was processed by pressing it into a web of Cerex 23 non-woven nylon material between two heated steel rolls. The rotational speed of the rolls was set as such to have a surface speed of 20 inches/minute. Both rolls were internally heated with recirculating hot oil. An oil set point of 160° C. in the heater produced a roll surface temperature on both the plate and blotter rolls of approximately 135° C. based on measurement of an infrared temperature meter. The gap between the two heated rolls was set to be narrow enough to facilitate transfer of resin from the plate to the blotter, but not so narrow as to crush the cured portions of the plate and damage the image.

After four blotter passes, the uncured resin areas were successfully removed. The non-image area was clean down to the primer layer. The reverse areas and text were clean and deep. Resolution was observed to be very good. Highlight dots better than 2% at 120 lpi were held. This good image quality of the invention example combined its desirable the hardness and resilience produced a flexographic printing plate ideal for high quality printing in a newspaper environment. The plate substrate exhibited no thermal elongation, shrinkage or other dimensional distortion. The ability of the metal substrate to withstand strong heating and conduct that heat into the relatively thin photopolymer layer of resin above it allowed for processing in only four passes with no loss in dimensional integrity of the plate.

### COMPARATIVE EXAMPLE

Resin mixing and plate making: The photopolymer resin described in Example 1 was heat pressed into a sheet with a thickness of 20 mils. This sheet was then laminated onto a length of 5 mil thick polyester substrate (Mitsubishi 4407) previously coated with a thin adhesive layer. Those skilled in the art will be familiar with adhesive layers available to bond photopolymers to polyester substrates. See for example U.S. Pat. No. 5,187,044, the teachings of which are incorporated herein in their entirety. The total plate thickness (substrate plus relief layer) was approximately 25 mils. A coversheet carrying a Macromelt 6900 slip film layer was laminated onto the surface.

Plate Imaging and Thermal Processing: After removal of the coversheet, this plate construction was image-wise exposed through a film negative for 10 minutes on a Supratech Systems FB3 exposure unit equipped with 10R UV lamps.

Thermal processing of the exposed plate was carried out in a manner similar to that described in the invention example. With roll face temperatures set to 135° C. (oil set point temperature of 160° C.), the polyester-backed flexo plate was fed into the roll nip and thereby impressed into a web of Cerex 23 non-woven nylon material. After only two passes, however, the 5 mil polyester substrate was badly distorted while the uncured areas of the plate remained incompletely processed. The polyester substrate was severely rippled and bowed so as to be unusable in any printing application. This clearly demonstrates the deficiency of polyester substrates in high temperature thermal plate processing.

Thermal processing was attempted again, this time using a lower face temperature of the roll next to the plate sample in order to reduce its heat exposure. The roll on the plate side was set to a face temperature of 45° C. The roll on the blotter side was set for a face temperature of 135° C. as in the invention example.

After four blotter passes the polyester substrate remained flat and uniform, but only about 8.0 mils of resin had been removed. The processing was incomplete. Clearly visible were significant amounts of uncured resin remaining in the non-image areas of the plate. Additional passes of the plate across the blotter were carried. Finally, after a total of 11 passes, the plate was clean of uncured resin down to the substrate and considered complete. The image quality was good and considered of acceptable quality for newspaper printing.

These additional blotter passes, however, more than doubled the time needed to process the plate and more than doubled the quantity and cost of the blotter needed, as compared to the invention example. Newspapers and other high productivity users seek the most rapid and cost effective methods to process their flexographic plates. This example illustrates the significant reduction in plate processing speed that is caused by using a roll temperature low enough to obviate the distortion of the polyester substrate.

1. A process for the manufacture of flexographic printing plates, said process comprising:
a. selectively exposing certain areas of a printing plate element to actinic radiation, wherein the printing plate element comprises:
1. a metallic substrate; and
2. a photopolymer layer, comprising one or more binder(s), monomer(s) and photoinitiator(s), upon said metallic substrate wherein the thickness of said photopolymer layer is not more than about 22 mils, the durometer of the photopolymer layer, when cured, is at least 55 Shore A and wherein the photopolymer layer comprises not more than about 82% by weight binder(s);
such that selected portions of the photopolymer layer are cured;
b. heating the printing plate element to at least 70° C., thereby selectively softening or melting portions of the photopolymer layer; and
c. contacting the heated printing plate element with a material which will absorb or otherwise remove the softened or melted portions of the photopolymer layer.

2. A process according to claim 1 wherein the binder of the photopolymer layer comprises at least one material selected from the group consisting of styrene-isoprene-styrene block co-polymers, and styrene-butadiene-styrene block co-polymers.

3. A process according to claim 1 wherein the thickness of the metallic substrate is from 3 to 14 mils.

4. A process according to claim 1, wherein the photopolymer has a melt flow index of at least 0.5 gr/10 minutes at 140° C.

5. A process according to claim 1 wherein the thickness of the metallic substrate is between 5 and 11 mils.
